(19) United States
(12) Patent Application Publication
(10) Pub. No.: US 2005/0099773 A1
(43) Pub. Date: May 12, 2005

(54) Cooling device for a motor vehicle having a cooling duct for a coolant

(75) Inventors: Eugen Bernarding, Usingen (DE); Christian Reimann, Wehrheim (DE); Herbert Severien, Linsengericht (DE)

Correspondence Address: SIEMENS SCHWEIZ;I-44, INTELLECTUAL PROPERTY, ALBISRIEDERSTRASSE 245, ZURICH, CH-8047, CH

(73) Assignee: SIEMENS AKTIENGESELLSCHAFT, MUNICH (DE)

(21) Appl. No.: 11/015,004

(22) Filed: Dec. 20, 2004

Related U.S. Application Data
(63) Continuation of application No. PCT/DE03/03017, filed on Sep. 11, 2003.

(30) Foreign Application Priority Data
Apr. 10, 2002 (DE) 102 46 349.2

(51) Int. Cl. H05K 7/20

(52) U.S. Cl. 361/699; 257/714; 257/724

(57) ABSTRACT

Electronic components are arranged outside of the cooling channel of a motor vehicle's engine.

The invention relates to a cooling device for a motor vehicle having a cooling duct for a coolant. Cooling devices for motor vehicles are known. They are usually a water cooler in which the water is conducted through a duct system, which is brought about using liquid pumps. Such cooling devices are generally used to cool the engine.

The invention is based on the object of providing a cooling device for a motor vehicle which both fulfills the function of cooling the engine and performs a further function.

The object on which the invention is based is achieved by means of a cooling device in which electronic components are arranged on the outside of the cooling duct. Electronic components used here may be, for example, capacitors, processors or transistors. They are usually used to electronically control or regulate processes in the motor vehicle. The outside of the cooling duct is understood as the outsides of the helical housing or of the hoses or of the valves which are embedded in the cooling circuit. The electronic components can be arranged on the outside of the cooling duct by, for example, clamping or by screwing. It has surprisingly been found that the cooling device for a motor vehicle can also be used to cool electronic components in such a way that the high temperatures to which they are normally directly subjected cannot cause any disadvantageous damage. As a result, it is possible to use electronic components which are more temperature-sensitive and thus more economical. The cooling effect is brought about here by arranging the electronic components in the vicinity of the coolant, water usually being used as the coolant.

One preferred refinement of the invention is to arrange electronic components for controlling or regulating the pump for conveying the coolant on the outside of the cooling duct. Since the pump for conveying the coolant is likewise arranged directly on the cooling duct for the coolant and likewise must be actuated by means of electronic components, it is particularly advantageous to arrange these electronic components both in the direct vicinity of the pump and on the outside of the cooling duct so that the electronic components can be advantageously cooled.

According to a further preferred refinement of the invention, the electronic components are connected to the cooling duct by means of an angled element. Only the angled element is located between the electronic components and the cooling duct, said angled element being usually composed of metal and being able to conduct the heat away to the coolant in a particularly advantageous fashion via the cooling duct. It is advantageous here that the electronic components can be cooled by the coolant even if there is no installation space available to arrange the electronic components directly on the outside of the cooling duct. Furthermore, the electronic components can be attached in a relatively simple configuration on the angled element.

According to a further preferred refinement of the invention there is provision for the electronic components to be attached with a bonded connection. It is advantageous here that additional attachment means such as, for example, screws or rivets can be entirely dispensed with.

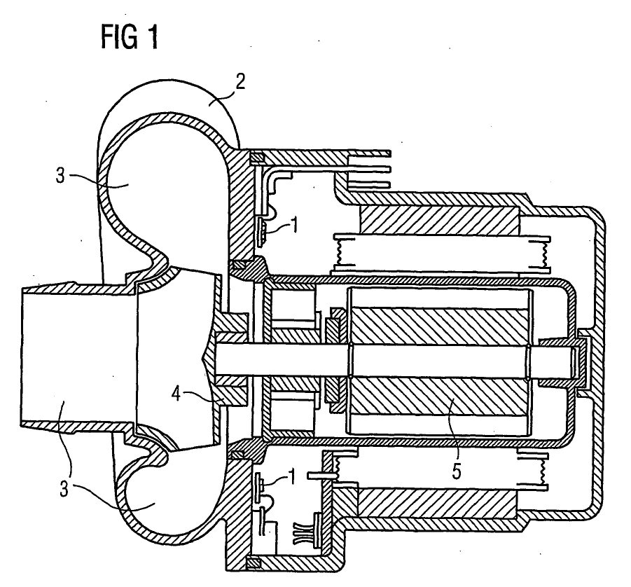

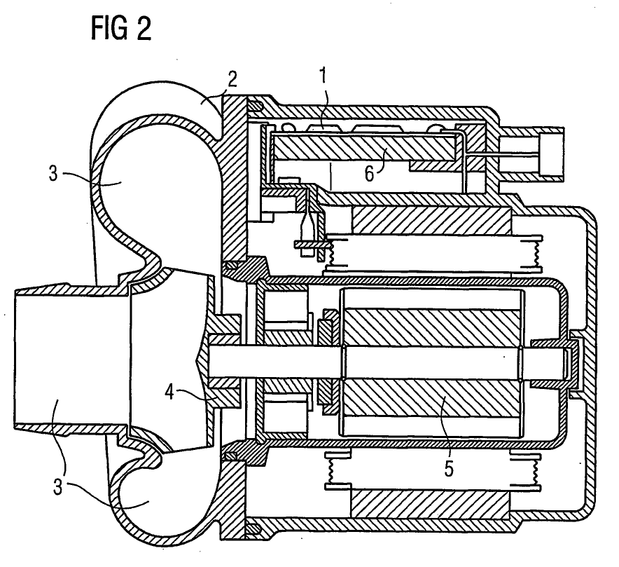

The invention will be explained in more detail below by way of example with reference to the drawing (FIG. 1, FIG. 2).

FIG. 1 shows the cooling device for a motor vehicle in cross section with the pump for conveying the coolant.

FIG. 2 shows the cooling device for a motor vehicle in cross section with the angled element.

FIG. 1 illustrates the cooling device for a motor vehicle with a cooling duct 3 for a coolant in cross section. Electronic components 1 are arranged on the outside of the cooling duct. A pump 5 with an impeller 4 which projects directly into the cooling duct 3 serves to convey the coolant. The electronic components 1 are arranged directly on the outside 2 of the cooling duct 3. The attachment here can be particularly advantageously effected by bonding.

FIG. 2 illustrates the cooling device for a motor vehicle in cross section with an angled element 6. The electronic components 1 are connected to the cooling duct 3 by means of the angled element 6. The angled element 6 is usually composed of metal and conducts the heat from the electronic components 1 into the coolant via the outside 2 of the cooling duct 3.

1. A cooling device for a motor vehicle having a cooling duct for a coolant, comprising: electronic components arranged on an outside of the cooling duct, the components being attached with a bonded connection.

2. The cooling device as claimed in claim 1, wherein the motor vehicle further comprises a pump arranged to convey coolant through the cooling duct, and the electronic components are arranged outside of the cooling duct to control or regulate the pump.

3. The cooling device according to claim 1, where the electronic components are connected to the cooling duct via an angled element.

4. (canceled)

5. The cooling device according to claim 2, wherein the electronic components are connected to the cooling duct via an angled element.
